(19) United States
(12) Patent Application Publication
(10) Pub. No.: US 2026/0332913 A1
(43) Pub. Date: Oct. 22, 2026

(54) IMAGING DEVICE AND METHOD OF OPERATING THE IMAGING DEVICE

(71) Applicant: SK hynix Inc., Icheon-si (KR)

(72) Inventors: Eun Khwang LEE, Icheon-si (KR); Ga Young KEUM, Icheon-si (KR)

(21) Appl. No.: 19/364,394

(22) Filed: Oct. 21, 2025

(30) Foreign Application Priority Data
Apr. 21, 2025 (KR) 10-2025-0051391

(51) Int. Cl. H04N 25/76; H04N 25/77; H04N 25/616; H04N 25/78

(52) U.S. Cl. CPC H04N 25/7795; H04N 25/77; H04N 25/616; H04N 25/78

(57) ABSTRACT

Embodiments of the disclosed technology provide an imaging device and a method of operating the imaging device. The imaging device includes a pixel array comprising first pixels arranged in a first pixel row along a first direction, and second pixels arranged in a second pixel row along the first direction, wherein the second pixel row is spaced apart from the first pixel row along a second direction intersecting the first direction; a first row driver configured to supply a first control signal to the first pixels of the first pixel row; and a second row driver configured to supply a second control signal to the second pixels of the second pixel row, wherein the first control signal and the second control signal are different from each other.

### PRIORITY CLAIM AND CROSS REFERENCE TO RELATED PATENT APPLICATION

This patent document claims priority to and the benefit of Korean Patent Application No. 10-2025-0051391, filed on Apr. 21, 2025, the disclosure of which is incorporated herein by reference in its entirety.

### TECHNICAL FIELD

Embodiments of the disclosed technology relate to an imaging device and a method of operating the imaging device.

### BACKGROUND

With the development of the information and communication industry and the digitalization of electronic devices, image sensors with improved performance are being used in various fields such as digital cameras, camcorders, mobile phones, PCS (personal communication systems), game devices, security cameras, and medical micro cameras. In general, an image sensor has a pixel area including a photodiode and a peripheral circuit area. A unit pixel includes a photodiode and a transistor. The transistor is placed between the photodiode and a floating diffusion area to transfer charges generated by the photodiode to the floating diffusion area.

### SUMMARY

Implementations of the disclosed technology can solve disadvantages of the prior art and provide an imaging device capable of providing an optimal voltage to a transfer transistor.

Implementations of the disclosed technology can provide an imaging device capable of providing an optimal voltage to a boosting control line, and a method of operating the same.

Implementations of the disclosed technology can provide an imaging device capable of securing an optimal driving time (or optimal duration) of a control signal applied to a gate electrode of a transfer transistor, and a method of operating the same.

The disclosed technology can provide an imaging device that may secure the optimal driving time (or optimal duration) of a control signal applied to a boosting control line, and a method of operating the same.

The disclosed technologies are not limited to those mentioned above, and various implementations may be inferred from following embodiments.

In one aspect, an imaging device may include a pixel array comprising a pixel array comprising first pixels arranged in a first pixel row along a first direction, and second pixels arranged in a second pixel row along the first direction, wherein the second pixel row is spaced apart from the first pixel row along a second direction intersecting the first direction; a first row driver configured to supply a first control signal to the first pixels of the first pixel row; and a second row driver configured to supply a second control signal to the second pixels of the second pixel row, wherein the first control signal and the second control signal are different from each other.

In another aspect, an imaging device may include a pixel array comprising a first pixel row of first pixels arranged along a first direction, and a second pixel row of second pixels arranged along the first direction, wherein the second pixel row is spaced apart from the first pixel row along a second direction intersecting the first direction; a first row driver configured to supply a first control signal of a first duration to the first pixels of the first pixel row; and a second row driver configured to supply a second control signal of a second duration to the second pixels of the second pixel row, wherein the first duration and the second duration are different from each other.

In a further aspect, a method of operating an imaging device is provided. The method includes determining an average voltage value of a control signal of pixels of a pixel row among a plurality of pixel rows included in the imaging device; storing the average voltage value of the control signal in a data memory; outputting a control signal based on the average voltage value to the pixel row from a row driver among a plurality of row drivers included in the imaging device; and applying the average voltage value to the pixel row.

In a still further aspect, a method of operating an imaging device is provided. The method includes determining an average duration of a control signal of pixels of a pixel row among a plurality of pixel rows included in the imaging device; storing the average duration of the control signal in a data memory; outputting the control signal with the average duration to the pixel row from a row driver among a plurality of row drivers included in the imaging device; and applying the control signal with the average duration to the pixel row.

Further scope of applicability of the implementations of disclosed technology will become apparent from the detailed description given hereinafter.

Based on some embodiments, by supplying transfer control signals having an average optimal voltage value to pixels in different pixel rows through separate row drivers, an optimal voltage value may be provided to pixels in a pixel array.

Based on some embodiments, by supplying a boosting control signal having an average optimal voltage value to pixels in different pixel rows through separate row drivers, an optimal voltage value may be provided to pixels in a pixel array.

Based on some embodiments, by supplying transfer control signals having an average optimal duration to pixels in different pixel rows through separate row drivers, transfer control signals driving pixels in a pixel array with an optimal duration may be applied.

Based on the embodiments, by supplying boosting control signals having an average optimal duration to pixels in different pixel rows through separate row drivers, a boosting control signal driving the pixels in the pixel array with an optimal duration may be applied.

However, it should be understood that the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF DRAWINGS

FIG. 1 is a block view showing an imaging system based on some implementations of the disclosed technology.

FIG. 2 is a block view of an image sensing unit based on some implementations of the disclosed technology.

FIG. 3 is circuit view of a pixel of a pixel array based on some implementations of the disclosed technology.

FIG. 4 is a timing view of one pixel based on some implementations of the disclosed technology.

FIG. 5 is a view showing storing of image data output from one pixel based on some implementations of the disclosed technology.

FIG. 6 is a view showing supplying average optimal voltage values to multiple pixel rows based on some implementations of the disclosed technology.

FIG. 7 is a flow chart showing a method of operating an imaging device based on some implementations of the disclosed technology.

FIG. 8 is a block view of an image sensing unit based on some implementations of the disclosed technology.

FIG. 9 is a diagram showing providing an optimal voltage value to multiple pixel rows of an image sensing unit based on some implementations of the disclosed technology.

FIG. 10 is a flow chart showing a method of operating an imaging device based on some implementations of the disclosed technology.

FIG. 11 is a timing view showing that a transfer transistor of a pixel operates at an optimal driving time based on some implementations of the disclosed technology.

FIG. 12 is a timing diagram showing that a transfer transistor of a pixel operates at an optimal driving time based on some implementations of the disclosed technology.

FIG. 13 is a block diagram of an image sensing unit based on some implementations of the disclosed technology.

FIG. 14 is a timing view of one pixel based on some implementations of the disclosed technology.

FIG. 15 is a flow chart showing a method of operating an imaging device based on some implementations of the disclosed technology.

FIG. 16 is a flow chart showing a method of operating an imaging device based on some implementations of the disclosed technology.

FIG. 17 is a timing view showing that a booting control line of one pixel operates at an optimal driving time based on some implementations of the disclosed technology.

### DETAILED DESCRIPTION

Description will now be given in detail based on exemplary embodiments disclosed herein, with reference to the accompanying drawings.

For the sake of brief description with reference to the drawings, the same or equivalent components may be provided with the same reference numbers. and description thereof will not be repeated. "And/or" includes any combination of one or more of the associated configurations that can be defined.

These terms are generally only used to distinguish one element from another. It will be understood that the terms “first” and “second” are used herein to describe various components but these components should not be limited by these terms. The above terms are used only to distinguish one component from another. For example, a first component may be referred to as a second component and vice versa without departing from the scope of the invention. The singular expressions include plural expressions unless the context clearly dictates otherwise.

Terms such as “comprise” or “include” are used herein and should be understood that they are intended to indicate an existence of several components, functions or steps, disclosed in the specification, and it is also understood that greater or fewer components, functions, or steps may likewise be utilized. However, the present disclosure may be embodied in various modified examples, and is not limited to embodiments described herein.

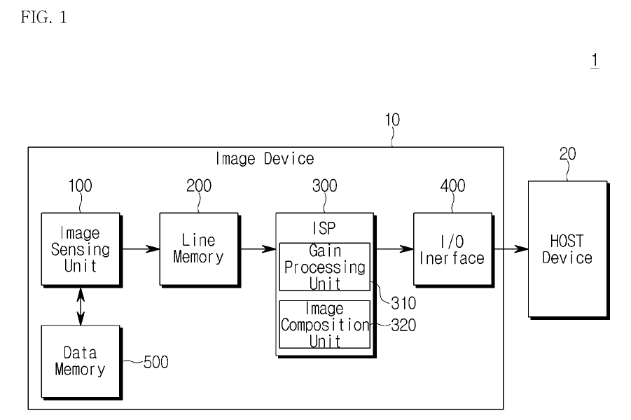

FIG. 1 is a block view showing an imaging system based on one embodiment.

Referring to FIG. 1, the imaging system 1 may mean not only a device such as a digital still camera that images still images or a digital video camera that images moving images, but also a device that detects motion. For example, the imaging system 1 may be implemented as a digital single lens reflex (DSLR) camera, a mirrorless camera, or a mobile phone (particularly, a smartphone), but is not limited thereto. The imaging system 1 may be a concept that includes a device that can capture a subject and generate an image by including a lens and an imaging element.

The imaging system 1 may include an imaging device 10 and a host device 20.

The imaging device 10 may include an image sensing unit 100, a line memory 200, an image signal processor ISP 300, an input/output interface (I/O interface) 400, and a data memory 500.

The image sensing unit 100 may be a CIS (Complementary Metal Oxide Semiconductor Image Sensor) that converts an optical signal into an electrical signal. The overall operation of the image sensing unit 100, such as on/off, operation mode, operation timing, and sensitivity, may be controlled by the ISP 300. The image sensing unit 100 may transmit image data converted from an optical signal into an electrical signal to the line memory 200 under the control of the ISP 300.

The line memory 200 may include volatile memory (e.g., DRAM, SRAM) and/or nonvolatile memory (e.g., flash memory).

The line memory 200 may receive and store image data from the image sensing unit 100, and transmit the stored image data to the ISP 300 under the control of the ISP 300.

The ISP 300 may perform image signal processing on the image data stored in the line memory 200. The ISP 300 may perform image signal processing for reducing noise on the image data and improving image quality, such as gamma correction, color filter array interpolation, color matrix, color correction, color enhancement, and lens distortion correction.

To generate an HDR image, the ISP 300 may include a gain processing unit 310 and an image compositing unit 320.

The gain processing unit 310 may determine a gain to be operated on image data (e.g., a multiplication operation). The gain processing unit 310 may determine a gain based on a difference in conversion gain between a high conversion gain (HCG) mode and a low conversion gain (LCG) mode and provide the gain to the image compositing unit 320.

Each pixel of the pixel array 110 may operate in either the HCG mode or the LCG mode, and the mode of each pixel may be determined by the intensity (or illuminance) of light incident on each pixel.

The image compositing unit 320 may synthesize an HDR image corresponding to a high dynamic range using image data of pixels operating in HCG mode and/or image data of pixels operating in LCG mode.

The ISP 300 may transmit image data (i.e., HDR image) subjected to image signal processing to the input/output interface 400.

Based on another embodiment, the gain processing unit 310 and the image compositing unit 320 for generating an HDR image may be included in the image sensing unit 100 rather than the ISP 300.

The input/output interface 400 performs communication with the host device 20 and can transmit image data subjected to image signal processing to the host device 20.

The host device 20 may be a processor (e.g., an application processor) that processes image data processed from a video signal received from the imaging device 1, a memory (e.g., a nonvolatile memory) that stores image data, or a display device (e.g., a liquid crystal display (LCD)) that visually outputs the image data.

The data memory 500 may store image data (Data_PX) in digital format converted from an analog-to-digital converter 140.

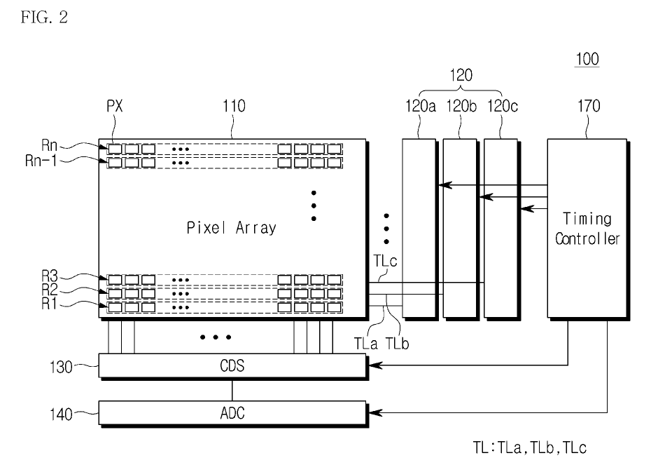

FIG. 2 is a block view of an example of an image sensing unit 100 based on one embodiment.

The image sensing unit 100 in FIG. 2 may include a pixel array 110, a timing controller 170, a double correlated sampler 130, and an analog-to-digital converter (ADC) 140.

Referring to FIG. 2, the pixel array 110 may include a plurality of pixels PX that include photoelectric conversion elements or photodetectors (PDs) operable to convert incident light into photocharges for the image sensing. The pixels PX may be arranged in a matrix manner along the row direction and the column direction, but the embodiments are not limited thereto. The pixels PX may include red pixels which include optical filters that transmit light in red to be received and detected by the corresponding photoelectric conversion elements (PDs), green pixels which include optical filters that transmit light in green to be received and detected by the corresponding photoelectric conversion elements or photodetectors (PDs), and blue pixels which include optical filters that transmit light in blue to be received and detected by the corresponding photoelectric conversion elements or photodetectors (PDs). However, the embodiments are not limited thereto, and may further include white pixels or infrared pixels.

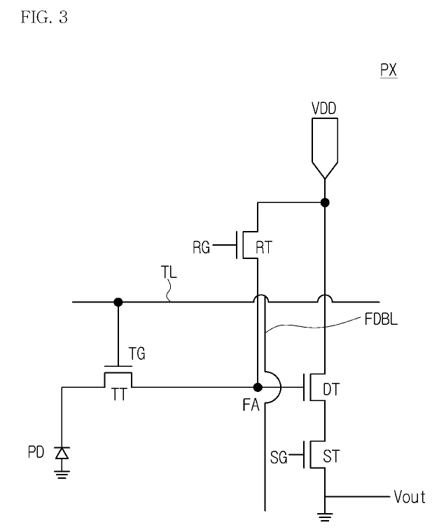

The plurality of pixels PX may be electrically connected to the row driver 120. The plurality of pixels PX may be respectively connected to control lines connected to the row driver 120. The control lines may be the transfer signal lines (TL), which is illustrated in FIG. 3, or the boosting control lines. In one embodiment as discussed below, the control line is described as a transfer signal line (TL). The description provided below in relation to the transfer signal line (TL) can be also applied to the boosting control line.

The row driver 120 may activate the pixel array 110 to perform specific operations on the pixels included in the corresponding row based on commands and control signals supplied by the timing controller 170.

The double correlated sampler 130 may transmit the reference signal and the image signal of each column as a correlated double sampling signal to the ADC 140 based on the control signal from the timing controller 170.

The ADC 140 may convert the correlated double sampling signal in the analog form for each column output from the double correlated sampler 130 into a digital signal and output image data. In one embodiment, the ADC 140 may convert the correlated double sampling signal generated by the double correlated sampler 130 for each column into a digital signal and output it.

The timing controller 170 may control at least one of the row driver 120, the double correlated sampler 130, and the ADC 140.

A plurality of pixels PX can be electrically connected to the row driver 120. The plurality of pixels PX may be respectively connected to control lines connected to the row driver 120. The control lines can be transfer control lines or boosting control lines. In one embodiment, the row driver 120 may be provided in multiple numbers. For example, the plurality of row drivers 120a, 120b, and 120c may provide different control signals to the corresponding pixel rows (R1, R2, R3, ..., Rn-1, Rn). The row drivers 120a, 120b, and 120c may include a first row driver 120a, a second row driver 120b, and a third row driver 120c. In FIG. 2, the number of row drivers 120 is exemplified as three, but the embodiments are not limited thereto. The plurality of row drivers 120a, 120b, and 120c may be positioned on one side (e.g., right side or left side) of the pixel array 110, but the embodiments are not limited thereto. For example, the plurality of row drivers 120a, 120b, and 120c may be positioned on the same position (one side, or right side, or left side) with respect to the pixel array 110.

The first row driver 120a may be connected to at least one pixel row among the plurality of pixel rows R1, R2, R3, ..., Rn-1, and Rn via the first transfer control line (TLa), the second row driver 120b may be connected to at least one pixel row among the plurality of pixel rows (R1, R2, R3, ..., Rn-1, Rn) that is not connected to the first row driver 120a via the second transfer control line TLb, and the third row driver 120c may be connected to at least one pixel row among the plurality of pixel rows (R1, R2, R3, ..., Rn-1, Rn) that is not connected to the first and second row drivers 120a and 120b via the third transfer control line (TLc). In FIG. 2, it is exemplarily shown that the first row driver 120a is connected to the first pixel row (R1), the second row driver 120b is connected to the second pixel row (R2), and the third row driver 120c is connected to the third pixel row (R3), but the embodiments are not limited thereto.

Each of the row drivers 120a, 120b, and 120c may provide an average optimal voltage value of a control signal to a corresponding plurality of pixel rows (R1, R2, R3, ..., Rn-1, Rn). The control signal may be a transfer control signal applied to a gate electrode of a transfer transistor which is further described with regard to FIG. 3.

FIG. 3 is circuit view of a pixel of a pixel array based on some implementations of the disclosed technology.

Referring to FIG. 3, the circuit diagram of the pixel may correspond to an equivalent circuit of each pixel (PX) included in the pixel array (see 110 of FIG. 2).

The pixel (PX) may include a photodetector or a photoelectric conversion element (PD), a transfer transistor (TT), a reset transistor (RT), a floating diffusion region (FA), a driver transistor (DT), and a selection transistor (ST). In the example, the pixel may have a structure of a 4TR (4-transistor) pixel, but the embodiments of the present specification are not limited thereto.

The photodetector (PD) may generate and accumulate photocharges corresponding to the intensity of incident light. For example, the photodetector (PD) may be implemented as a photodiode, a phototransistor, a photogate, a pinned photodiode, or a combination thereof. When the photodetector (PD) is implemented as a photodiode, it may be a region doped with an impurity of a second conductivity type (e.g., N type) within a substrate having a first conductivity type (e.g., P type).

A transfer transistor (TT) may be connected between the photodetector (PD) and the floating diffusion region (FA). The transfer transistor (TT) may be turned on or off in response to a transfer control signal (TX) applied to a gate electrode (TG), and the turned-on transfer transistor (TT) may transfer photocharges accumulated in the photodetector (PD) to the floating diffusion region (FA). A source electrode of the transfer transistor (TT) may be connected to the photodetector (PD), and a drain electrode may be connected to the floating diffusion region (FA).

The reset transistor (RT) is connected between the power supply voltage (VDD) and the floating diffusion region (FA), and can reset the voltage of the floating diffusion region (FA) to the power supply voltage (VDD) in response to a reset control signal (RX) applied to the gate electrode (RG). The power supply voltage (VDD) is applied to the source electrode of the reset transistor (RT), and the drain electrode can be connected to the floating diffusion region (FA).

The floating diffusion region (FA) may accumulate photocharges transferred from the transfer transistor (TT). For example, the floating diffusion region (FA) can be a region doped with an impurity of a second conductivity type (e.g., an N type) in a substrate having a first conductivity type (e.g., a P type), and the substrate and the impurity doped region can be modeled as a junction capacitor. The floating diffusion region (FA) can be connected to the gate electrode of the driver transistor (DT), the drain electrode of the transfer transistor (TT), and the drain region of the reset transistor (RT). A floating diffusion electrode can be arranged in the floating diffusion region (FA).

The driver transistor (DT) is connected between the power supply voltage (VDD) and the selection transistor (ST), and may amplify the change in the electric potential of the floating diffusion region (FA) that receives the photocharge accumulated in the photodetector (PD) and transfer it to the selection transistor (ST). The gate electrode of the driver transistor (DT) may be connected to the floating diffusion region (FA), the power supply voltage (VDD) is applied to the source electrode, and the drain electrode may be connected to the source electrode of the selection transistor (ST).

The selection transistor (ST) is connected between the driver transistor (DT) and the output signal line (or column line), and is turned on by a row selection control signal (SX) applied to the gate electrode (SG) to output an electrical signal transmitted from the driver transistor (DT) as a pixel signal (Vout). The source electrode of the selection transistor (ST) may be connected to the drain electrode of the driver transistor (DT).

The voltage of the floating diffusion region (FA) may be determined by the amount of photocharge transmitted through the transfer transistor (TT), and the voltage of the floating diffusion region (FA) may be lowered as the amount of photocharge increases.

The floating diffusion region (FA) (or the floating diffusion electrode) may form a capacitance with the boosting control line (FDBL). By applying the boosting control signal (FDB) via the boosting control line (FDBL), the boosting control line (FDBL) can influence the voltage of the floating diffusion region through the capacitive coupling.

Each of the control signals including transfer control signal (TX), the reset control signal (RX), the row select control signal (SX), and the boosting control line (FDBL) may be supplied from the row driver 120, but the embodiments are not limited thereto.

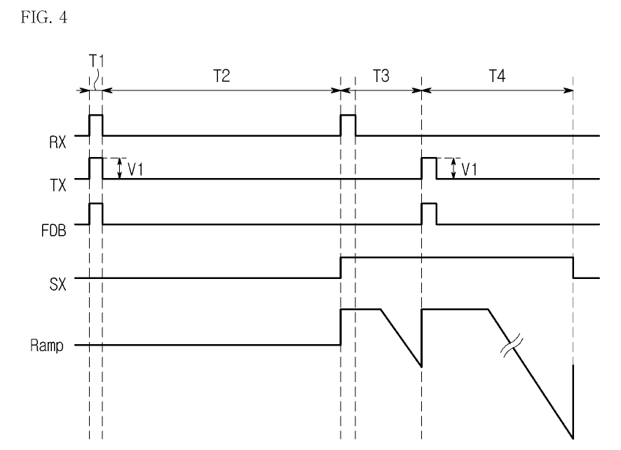

FIG. 4 is a timing view of one pixel based on some implementations of the disclosed technology.

In the example, the reset period is referred to as the first period (T1), the light irradiation period is referred to as the second period (T2), and the read period is referred to as the third and fourth periods (T3, T4). The third period (T3) may be an FD reset period, and the fourth period (T4) may be a read-out period. The first period (T1) may be a PD reset period.

Referring to FIG. 4, the transfer control signal (TX) has the voltage (V1) applied to the gate electrode of the transfer transistor (TT). The activation/deactivation of the transfer transistor (TT) may be determined based on the magnitude of the voltage (V1). While the voltage (V1) refers to the actual voltage applied to the gate electrode of the transfer transistor (TT), an optimal voltage value refers to the voltage required to turn on the transfer transistor (TT). Optimal voltage values for turning on the transfer transistors (TT) in each individual pixel (PX) of FIG. 2 may be different from each other. For example, optimal voltage values for three different pixels are different from one another.

In the description below, we assume that the optimal voltage value for turning on the transfer gate in the first pixel is greater than the voltage (V1), the optimal voltage value for turning on the transfer gate in the second pixel is less than the voltage (V1), and the optimal voltage value for turning on the transfer gate in the third pixel is same as the voltage (V1). In the below, it will be discussed how the differences between the voltage (V1) and a corresponding optimal voltage value in each pixel affects the image data output from each pixel. When applying the voltage (V1) to transfer gates in first to third pixels, the voltage (V1) applied to the transfer transistor in the first pixel is less than its optimal voltage value.

In the second pixel, the voltage (see V1 of FIG. 4) applied to the transfer transistor in the second pixel is greater than its optimal voltage value.

In the third pixel, the voltage (see V1 of FIG. 4) applied to the transfer transistor in the third pixel is same as its optimal voltage value.

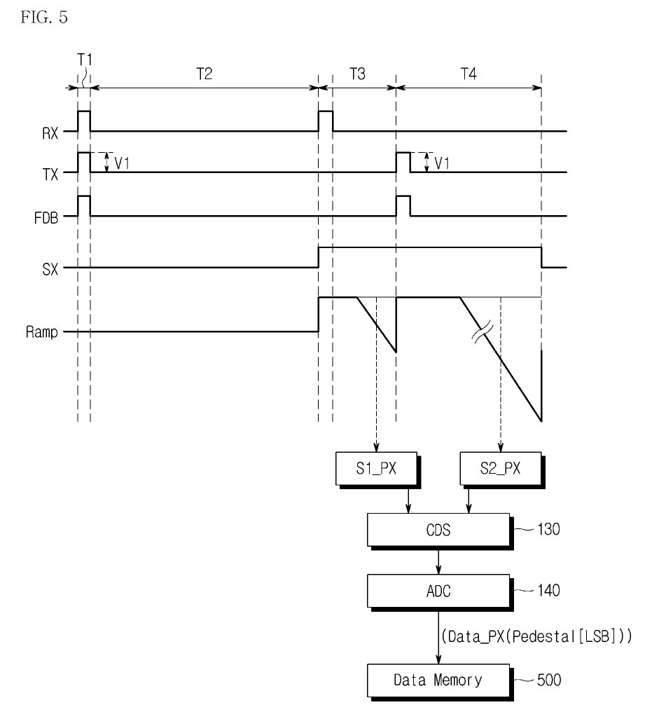

FIG. 5 is a view showing storing of image data output from one pixel based on some implementations of the disclosed technology. The view as shown in FIG. 5 can be applied to each of the first to third pixels. . In comparison to FIGS. 4,5 further shows that pixel signals (S1_PX, S2_PX) extracted (or generated) from the third period (T3) and the fourth period (T4) of the pixel are transmitted to the double correlated sampler 130.

Referring to FIG. 5, in the third period (T3), the first pixel signal (S1_PX) may be output to the output signal line, and in the fourth period (T4), the second pixel signal (S2_PX) may be output to the output signal line. The output pixel signals (S1_PX, S2_PX) are transmitted to the double correlated sampler 130. For example, the first pixel signal (S1_PX) may refer toa pixel signal corresponding to photocharges when the floating diffusion region is reset, and the second pixel signal (S2_PX) may refer to a pixel signal corresponding to photocharges accumulated in the floating diffusion region. The process of storing the pixel signals (S1_PX, S2_PX) extracted (or generated) from the third period (T3) and the fourth period (T4) of the pixel of FIG. 5 in the data memory 500 may be performed in the wafer test stage.

In some implementations, the generation of the pixel signals (S1_PX, S2_PX) may be performed in a white environment that is illuminated with a white light. However, the present embodiments are not limited thereto, and the generation of the pixel signals (S1_PX, S2_PX) may be performed in a black environment where the pixel signals are shielded from light.

For example, when an optimal voltage value is applied to the transfer transistor (TT) of the third pixel having its optimal voltage value same as the voltage (V1), the first pixel signal (S1_PX) has a first voltage value, the second pixel signal (S2_PX) has a second voltage value. The difference between the first voltage value and the second voltage value may correspond to the amount of photocharges applied to the photoelectric conversion element (PD) of the third pixel. The double correlated sampler 130 calculates the difference between the transmitted pixel signals (S1_PX, S2_PX) and provides it to the ADC 140. Accordingly, the ADC 140 may receive a value (hereinafter, a normal value) corresponding to the amount of photoelectric charge applied to the photoelectric conversion element (PD) and perform digital conversion and offset. For example, the ADC 140 converts and offsets the normal value provided from the double correlated sampler 130 into digital data and generates image data (Data_PX(Pedestal[LSB]), which may be 64[LSB]. For example, it is assumed that the normal value is set to 64[LSB]. The LSB means “least significant bit” and such LSB may be used a unit for a digital output of a pixel.

In the case of the first pixel, when the voltage (V1) is applied to the transfer transistor (TT), since the voltage (V1) is lower than the optimal voltage of the first pixel, the first pixel signal (S1_PX) may have a first voltage value, and the second pixel signal (S2_PX) may have a voltage higher than the second voltage value. Since the first pixel signal (S1_PX) corresponds to the photocharges when the floating diffusion is reset, the first voltage value is same as that in the third pixel. Accordingly, the ADC 140 may receive a voltage value higher than the normal value (hereinafter, the first abnormal value) and perform digital conversion and offset. For example, the ADC 140 converts and offsets the first abnormal value provided from the double correlated sampler 130 into digital data and generates image data (Data_PX(Pedestal[LSB]). and the value may be greater than 64 [LSB].

In the second pixel, when the voltage (V1) is applied to the transfer transistor (TT), since the voltage (V1) is greater than the optimal voltage value of the second pixel, the first pixel signal (S1_PX) may have a first voltage value, and the second pixel signal (S2_PX) may have a voltage smaller than the second voltage value. Since the first pixel signal (S1_PX) corresponds to the photocharges when the floating diffusion is reset, the first voltage value is same as that in the third pixel. Therefore, the ADC 140 may receive a voltage value smaller than the normal value (hereinafter, the second abnormal value) and perform digital conversion and offset. For example, the ADC 140 digitally converts and offsets the second abnormal value provided from the double correlated sampler 130 to generate image data (Data_PX(Pedestal[LSB]), the value of which may be less than 64 [LSB].

Based on the present embodiment, as described above, whether the voltage of the transfer control signal applied to the transfer transistor (TT) is same as an optimal voltage value, smaller than the optimal voltage value, or larger than the optimal voltage value affects the size of the image data (Data_PX) generated from each pixel (PX), while the image data (Data_PX) generated for each pixel (PX) can be stored in the data memory (500). The data memory 500 may store, based on the image data (Data_PX) of the pixels (PX) constituting each of the pixel rows (see R1, R2, R3, ∙∙∙, Rn-1, Rn of FIG. 2), an average optimal voltage value applied to the gate electrodes of the transfer transistors (TT) of each of the pixel rows (R1, R2, R3, ∙∙∙, Rn-1, Rn). For example, the data memory 500 may store a first average optimal voltage value corresponding to the transfer control signal of the pixels (PX) of at least one pixel row (e.g., including the first pixel row), a second average optimal voltage value corresponding to the transfer control signal of the pixels (PX) of at least one pixel row (e.g., including the second pixel row) to which the first average optimal voltage value is not applied, and the third average optimal voltage value corresponding to the transfer control signal of the pixels (PX) of at least one pixel row (e.g., including the third pixel row) to which the first and second average optimal voltage values are not applied can be stored.

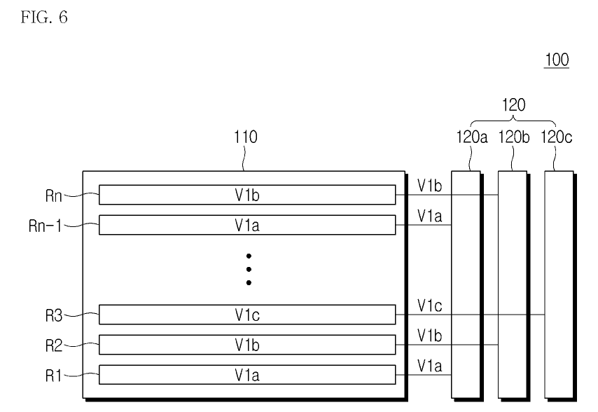

The above-described optimal voltage value can be determined in various manners. For example, while changing the value of the transfer control signal during the wafer test (WT) step in the case where the optimal voltage value is not applied to the transfer transistor (TT) of a pixel (PX) (i.e., when the image data (Data_PX) value of 64 [LSB] is not generated as in FIG. 5), the optimal voltage value of the transfer control signal of the pixel (PX) can be determined. The average of the optimal voltage values of the pixels (PX) constituting each pixel row can be calculated for each pixel row. Therefore, the optimal voltage value of the transfer control signal of each pixel row can be stored in the data memory 500. The optimal voltage values of the transfer control signal of each pixel row can be different from each other. The row drivers 120a, 120b, and 120c of FIG. 6 may provide transfer control signals with different average optimal voltage values to the corresponding pixel rows based on the optimal voltage values of the transfer control signals for each pixel row stored in the data memory 500.

In some embodiments, the average optimal voltage values of the transfer control signals for each pixel row may be different from each other, but since the number of row drivers 120a, 120b, and 120c is limited, the transfer control signals may be provided to the respective pixel rows by dividing them by the range of the average optimal voltage values of the transfer control signals for each pixel row of each row driver 120a, 120b, and 120c. For example, a pixel row having a first average optimal voltage value range is connected to a first row driver 120a, a pixel row having a second average optimal voltage value range is connected to a second row driver 120b, and a pixel row having a third average optimal voltage value range is connected to a third row driver 120c. The first average optimal voltage value range, the second average optimal voltage value range, and the third average optimal voltage value range may be different from each other.

FIG. 6 is a view showing supplying average optimal voltage values to multiple pixel rows based on some implementations of the disclosed technology.

In the example of the image sensing unit 100 as shown in FIG. 6, a first average voltage value range (V1a) is supplied to the first pixel row (R1) of the image sensing unit 100, a second average voltage value range (V1b) is supplied to the second pixel row (R2), a third average voltage value range (V1c) is supplied to the third pixel row (R3), a first average voltage value range (V1a) is supplied to the n-1th pixel row (Rn-1), and a second average voltage value range (V1b) is supplied to the nth pixel row (Rn). Each average voltage value range (V1a, V1b, V1c) may be different from one another.

The first row driver 120a may provide the first average voltage value range (V1a) to the first pixel row (R1) and the n-1th pixel row (Rn-1), the second row driver 120b may provide the second average voltage value range (V1b) to the second pixel row (R2) and the nth pixel row (Rn), and the third row driver 120c may provide the third average voltage value range (V1c) to the third pixel row (R3).

Based on an embodiment of the imaging device, by supplying transfer control signals having an average optimal voltage value to pixels of different pixel rows through separate row drivers 120a, 120b, and 120c, the optimal voltage values may be provided to the pixels of the pixel array 110.

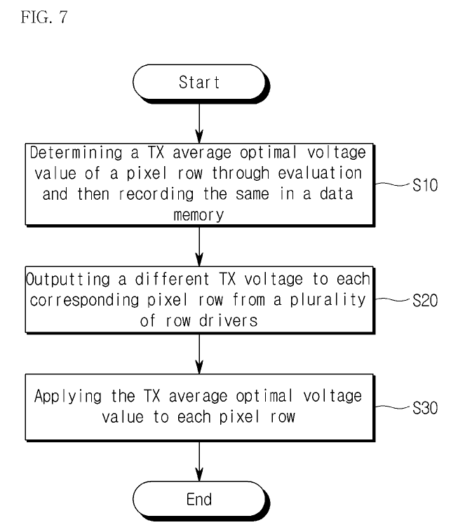

FIG. 7 is a flow chart showing a method of operating an imaging device based on one embodiment.

Referring to FIGS. 5 and 7, an operating method of an imaging device based on one embodiment includes a step (S10) of determining an average optimal voltage value of a transfer control signal (TX) of each pixel row through evaluation and then recording the same in a data memory 500. In this step, the evaluation may be performed in a black environment or white environment. In one embodiment, the description will focus on the evaluation in a white environment. In the step (S10) of determining an average optimal voltage value of a transfer control signal (TX) of each pixel row through evaluation and then recording the same in the data memory 500, the process of storing pixel signals (S1_PX, S2_PX) in the data memory 500 is performed in a wafer test step, and a dual correlation sampler 130 calculates a difference between transmitted pixel signals (S1_PX, S2_PX) for each individual pixel and provides the difference to an ADC 140. Therefore, the ADC 140 may receive a value (hereinafter, normal value) corresponding to the amount of photocharge applied to the photoelectric conversion element (PD), and perform digital conversion and offset.

The data memory 500 may store an average optimal voltage value that should be applied to the gate electrode of the transfer transistor (TT) of each of the pixel rows (R1, R2, R3, ∙∙∙, Rn-1, Rn) based on the image data (Data_PX) of the pixels (PX) constituting each of the pixel rows (see R1, R2, R3, ∙∙∙, Rn-1, Rn in FIG. 6). For example, the data memory 500 may store a first average optimal voltage value of the transfer control signal of the pixels (PX) of at least one pixel row (e.g., including the first pixel row (R1)), a second average optimal voltage value of the transfer control signal of the pixels (PX) of at least one pixel row (e.g., including the second pixel row (R2)) to which the first average optimal voltage value is not applied, and a third average optimal voltage value of the transfer control signal of the pixels (PX) of at least one pixel row (e.g., including the third pixel row (R3)) to which the first and second average optimal voltage values are not applied.

In the case where the optimal voltage value described above is not applied to the transfer transistor (TT) for each pixel (PX) (i.e., when the image data (Data_PX) value of 64 [LSB] is not generated as in FIG. 5), the first period (T1) to the fourth period (T4) of FIG. 5 can be repeated while changing the value of the transfer control signal at the wafer test (WT) stage. Accordingly, the optimized voltage value of the transfer control signal for each pixel (PX) can be found, and the average of the optimal voltage values of the pixels (PX) constituting each pixel row (R1, R2, R3, ∙∙∙, Rn-1, Rn) can be calculated for each pixel row (R1, R2, R3, ∙∙∙, Rn-1, Rn). Therefore, the optimal voltage value of the transfer control signal for each pixel row (R1, R2, R3, ∙∙∙, Rn-1, Rn) can be stored in the data memory 500. The optimal voltage values of the transfer control signals for each pixel row (R1, R2, R3, ∙∙∙, Rn-1, Rn) may be different from each other. The row drivers (120a, 120b, 120c) of FIG. 2 may provide transfer control signals having different average optimal voltage values to the corresponding pixel rows (R1, R2, R3, ∙∙∙, Rn-1, Rn) based on the optimal voltage values of the transfer control signals for each pixel row (R1, R2, R3, ∙∙∙, Rn-1, Rn) stored in the data memory 500.

Next, the method of operating the imaging device based on one embodiment includes a step (S20) of outputting a different voltage (or average optimal voltage value) of a transfer control signal (TX) to each corresponding pixel row from a plurality of row drivers (see 120a, 120b, and 120c of FIG. 2).

Next, the method of operating the imaging device based on one embodiment includes a step (S30) of applying an average optimal voltage value of the transfer control signal (TX) to each pixel row.

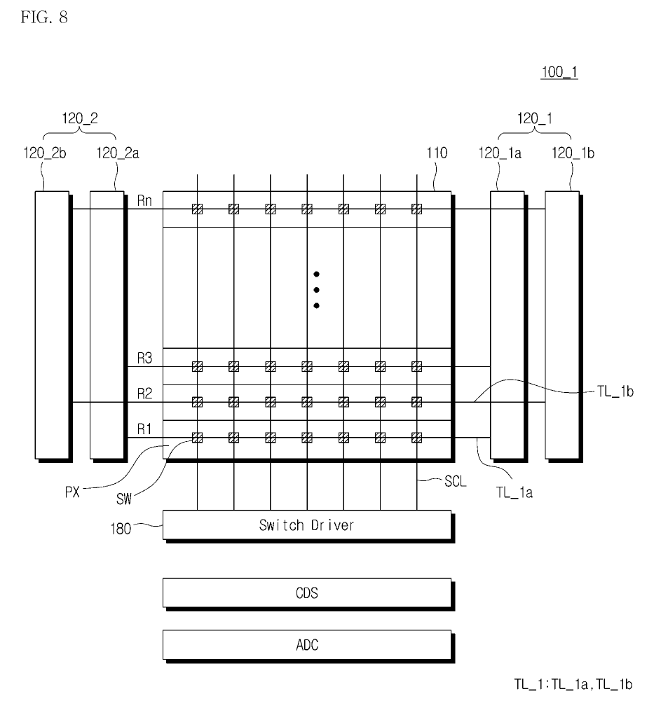

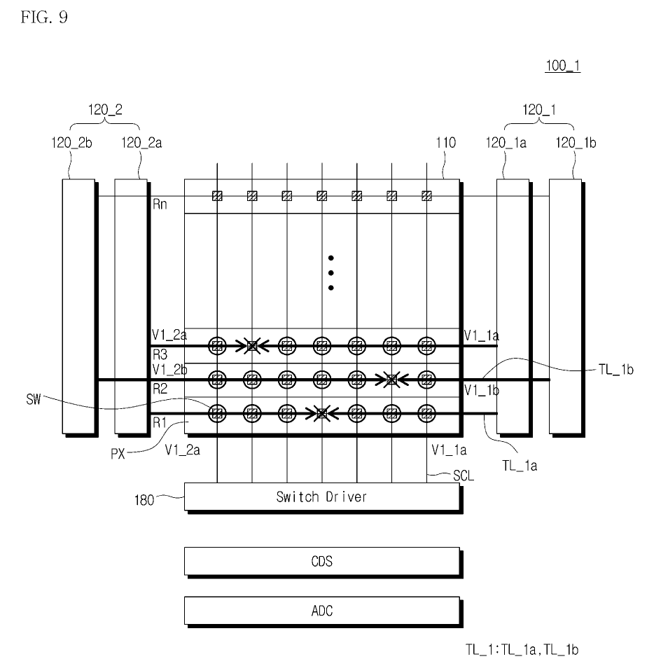

Hereinafter, with reference to FIGS. 8 and 9, the imaging device based on another embodiment will be described.

FIG. 8 is a block view of an image sensing unit based on another embodiment.

Referring to FIG. 8, the image sensing unit 100_1 of the imaging device based on the present embodiment is different from the imaging device based on FIG. 2 in that it includes a plurality of row drivers 120_1 and 120_2 and further includes a switch driver 180.

More specifically, the plurality of row drivers 120_1 and 120_2 may include a first row driver group 120_1 located on one side (or right) of the pixel array 110, and a second row driver group 120_2 located on the other side (or left). Each row driver group 120_1 and 120_2 may be provided in multiple numbers. For example, each row driver group 120_1 and 120_2 may be two, but the embodiments are not limited thereto. For example, the first row driver group 120_1 may include a first sub-row driver 120_1a located on one side of the pixel array 110, and a second sub-row driver 120_1b spaced apart from the pixel array 110 with the first sub-row driver 120_1a interposed therebetween, and the second row driver group 120_2 may include a third sub-row driver 120_2a located on the other side of the pixel array 110, and a fourth sub-row driver 120_2b spaced apart from the pixel array 110 with the third sub-row driver 120_2a interposed therebetween. Each of the row driver groups 120_1 and 120_2) may be connected to the pixel array 110 via a transfer control line (TL_1).

The first sub-row driver 120_1a and the third sub-row driver 120_2a may be connected to the same first transfer control line (TL_1a), and the second sub-row driver 120_1b and the fourth sub-row driver 120_2b may be connected to the same second transfer control line (TL_1b). A switch SW may be further arranged between each adjacent pixel PX. Each switch SW may be connected to a switch driver (Switch Driver, 180). That is, the switch driver 180 may provide a control signal for controlling on/off of each switch SW to the switches SW. The switch control signal SCL extends in the column direction and may be simultaneously connected to the switches SW arranged in the column direction.

FIG. 9 is a diagram showing providing an optimal voltage value to multiple pixel rows of an image sensing unit based on another embodiment. In FIG. 9, the state in which the switch (SW) is turned on is indicated by O, and the state in which it is turned off is indicated by X.

Referring to FIG. 9, the first sub-row driver 120_1a may output the first average optimal voltage value (V1_1a), the third sub-row driver 120_2a may output the third average optimal voltage value (V1_2a), the second sub-row driver 120_1b may output the second average optimal voltage value (V1_1b), and the fourth sub-row driver 120_2b may output the fourth average optimal voltage value (V1_2b). Each of the average optimal voltage values (V1_1a, V1_2a, V1_1b, V1_2b) can have different values. That is, the first sub-row driver 120_1a and the third sub-row driver 120_2a may be connected to the same first transfer control line (TL_1a), and the second sub-row driver 120_1b and the fourth sub-row driver 120_2b may be connected to the same second transfer control line (TL_1b), but the voltage values they output may be different from each other.

The first average optimal voltage value (V1_1a) output from the first sub-row driver 120_1a may be supplied only to the pixels PX located before the turned-off switch SW. The third average optimal voltage value (V1_2a) output from the third sub-row driver 120_2a may be supplied only to the pixels PX located before the turned-off switch SW. The second average optimal voltage value (V1_1b) output from the second sub-row driver 120_1b may be supplied only to the pixels PX located before the turned-off switch SW. The fourth average optimal voltage value (V1_2b) output from the fourth sub-row driver 120_2b may be supplied only to the pixels PX located before the turned-off switch SW.

The description of other details is omitted below as described above in FIG. 2.

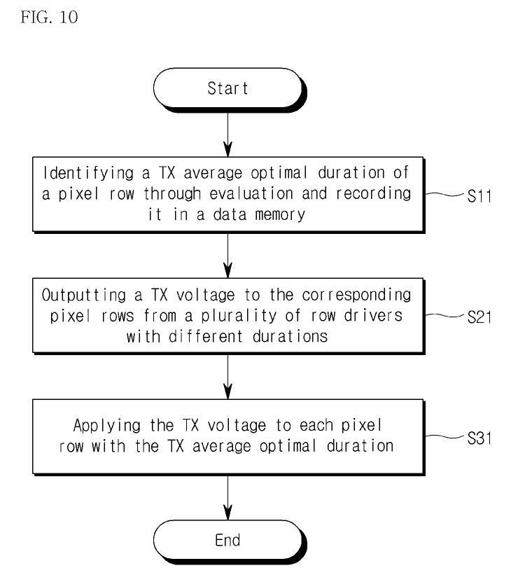

Hereinafter, with reference to FIGS. 10-12, a method of compensating for the duration of a transfer control signal (TX) and an imaging device for compensating will be described.

FIG. 10 is a flow chart showing a method of operating an imaging device based on another embodiment. The method of operating the imaging device based on FIG. 10 and the imaging device are the same as the imaging device described in FIG. 2, but the duration of the control signal (or transfer control signal (TX)) output from each row driver (see 120a, 120b, 120c of FIG. 2) may be different from each other. In the example, the structure of the imaging device based on the present embodiment may be the same as or similar to the imaging device described in FIGS. 2 or 8 .

Referring to FIGS. 5 and 10 , the method of operating the imaging device based on the present embodiment includes a step (S11) of identifying the average optimal duration of the transfer control signal (TX) of each pixel row through evaluation and then recording it in the data memory 500. In this step, the evaluation may be evaluation in a black environment or evaluation in a white environment, and in one embodiment, the description will be centered on the evaluation in a white environment. In this embodiment, the description will be centered on the evaluation in a white environment. The above step (S11) is similar to the step (S10) described in FIG. 7, so a redundant description will be omitted.

Next, the method of operating the imaging device based on the present embodiment includes a step (S21) of outputting the voltage of the transfer control signal (TX) to the corresponding pixel rows from a plurality of row drivers (see 120a, 120b, and 120c of FIG. 2) with different durations.

Next, the method of operating the imaging device based on the present embodiment includes a step (S31) of applying the transfer control signal (TX) to each pixel row with an average optimal duration.

Based on the present embodiment, the optimal duration of the transfer control signal (TX) may be different for each pixel, and the duration of the transfer control signal (TX) applied to each pixel row can be optimized through the transfer control signal (TX) output from different row drivers 120a and 120b.

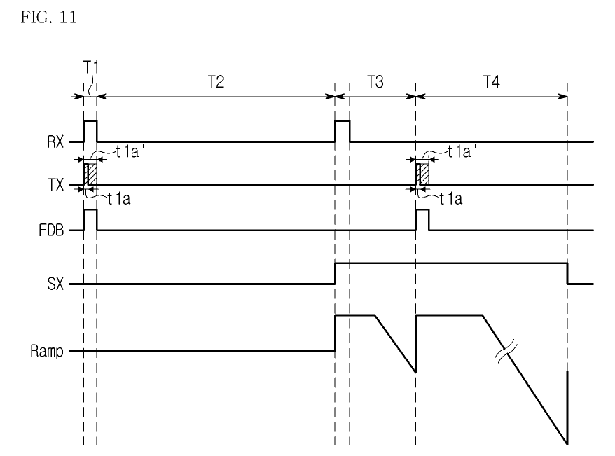

FIG. 11 is a timing view showing that a transfer transistor of a pixel based on another embodiment operates at an optimal driving time.

Referring to FIG. 11, the row driver (see 120a, 120b of FIG. 2) can supply a transfer control signal (TX) with an average optimal duration (t1a’) having the same time as the first period (T1) to the corresponding pixel row.

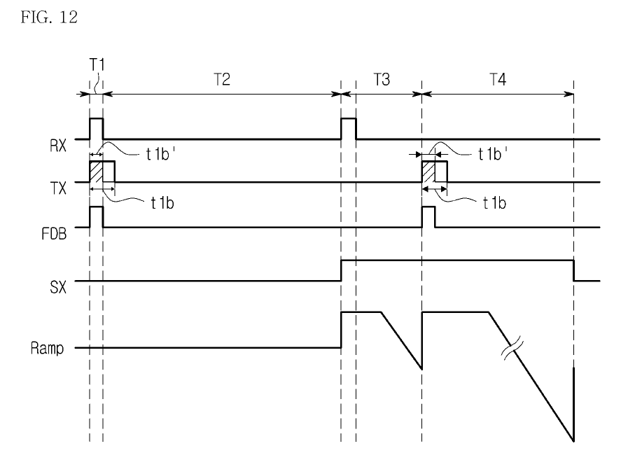

FIG. 12 is a timing diagram showing that a transfer transistor of a pixel based on another embodiment operates at an optimal driving time.

Referring to FIG. 12, the row driver (see 120a, 120b of FIG. 2) can supply a transfer control signal (TX) with an average optimal duration (t1b’) having the same time as the first period (T1) to the corresponding pixel row.

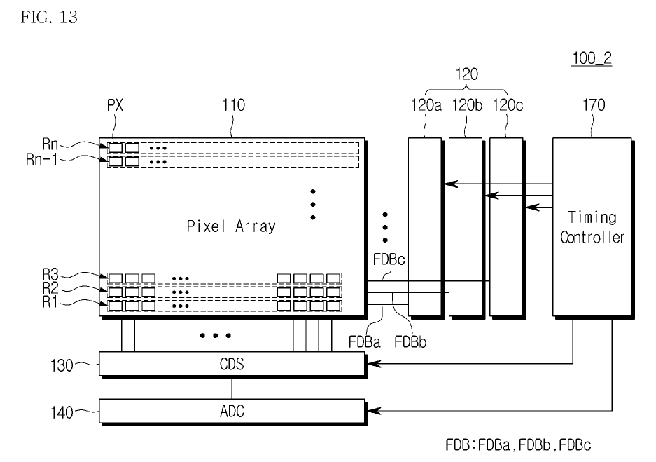

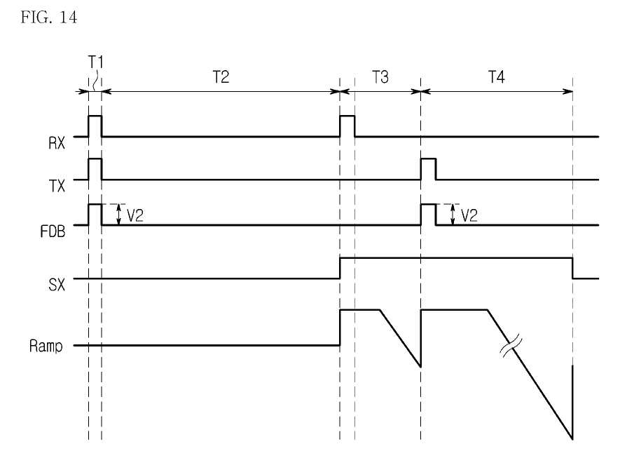

Hereinafter, the imaging device that optimizes a boosting control signal (FDB) will be described with reference to FIGS. 13 and 14 .

FIG. 13 is a block diagram of an image sensing unit based on another embodiment.

Referring to FIG. 13, a plurality of pixels PX of an imaging device 100_2 based on the present embodiment may be electrically connected to a row driver 120. The plurality of pixels PX may be respectively connected to control lines connected to the row driver 120. In the present embodiment, the control line is described as a boosting control line (FDBL). In the present embodiment, a plurality of row drivers 120 may be provided. For example, a plurality of row drivers 120a, 120b, and 120c may provide different control signals to corresponding pixel rows (R1, R2, R3, ..., Rn-1, Rn). The row drivers 120a, 120b, and 120c may include a first row driver 120a, a second row driver 120b, and a third row driver 120c. In FIG. 13, the number of row drivers 120 is exemplified as three, but the embodiments are not limited thereto. The plurality of row drivers 120a, 120b, and 120c may be positioned on one side (e.g., right or left) of the pixel array 110, but the embodiments of the present specification are not limited thereto. For example, the plurality of row drivers 120a, 120b, and 120c may be positioned on the same position (one side, or right side, or left side) with respect to the pixel array 110.

The first row driver 120a may be connected to at least one pixel row among the plurality of pixel rows (R1, R2, R3, ..., Rn-1, Rn) via the first boosting control line (FDBLa), the second row driver 120b may be connected to at least one pixel row among the plurality of pixel rows (R1, R2, R3, ..., Rn-1, Rn) that is not connected to the first row driver 120a via the second boosting control line (FDBLb), and the third row driver 120c may be connected to at least one pixel row among the plurality of pixel rows (R1, R2, R3, ..., Rn-1, Rn) that is not connected to the first and second row drivers 120a and 120b via the third boosting control line (FDBLc). In FIG. 13, the first row driver 120a is exemplarily connected to the first pixel row (R1), the second row driver 120b is connected to the second pixel row (R2), and the third row driver 120c is connected to the third pixel row (R3), but the embodiments are not limited thereto.

Each of the row drivers 120a, 120b, and 120c may provide an average optimal voltage value of a control signal to a corresponding plurality of pixel rows (R1, R2, R3, ..., Rn-1, Rn). The control signal may be a boosting control signal (FDB) applied to a boosting control line (FDBL).

The timing controller 170, the double correlated sampler 130, and the ADC 140 illustrated in FIG. 13 are the same as those described in FIG. 2, so a duplicate description thereof will be omitted.

FIG. 14 is a timing view of one pixel based on some implementations of the disclosed technology.

Referring to FIG. 14, in the first period (T1) and the fourth period (T4) of the pixel based on the present embodiment, the boosting control signal (FDB) may have the second voltage (V2).

In the present embodiment, as described above in relation to FIG. 5, depending on whether the boosting control signal applied to the boosting control line (FDBL) is an optimal voltage value, smaller than the optimal voltage value, or larger than the optimal voltage value, the size of the image data (Data_PX) generated from each pixel (PX) is different, while the image data (Data_PX) generated for each pixel (PX) may be stored in the data memory 500. The data memory 500 may store an average optimal voltage value that needs to be applied to the boosting control line (FDBL) of each pixel row (R1, R2, R3, ∙∙∙, Rn-1, Rn) based on the image data (Data_PX) of the pixels (PX) constituting each of the pixel rows (see R1, R2, R3, ∙∙∙, Rn-1, Rn in FIG. 13). For example, the data memory 500 may store a first average optimal voltage value of the boosting control signal of the pixels (PX) of at least one pixel row (e.g., including the first pixel row (R1)), a second average optimal voltage value of the boosting control signal of the pixels (PX) of at least one pixel row (e.g., including the second pixel row (R2)) to which the first average optimal voltage value is not applied, and a third average optimal voltage value of the boosting control signal of the pixels (PX) of at least one pixel row (e.g., including the third pixel row (R3)) to which the first and second average optimal voltage values are not applied.

The above-described optimal voltage value can be determined in various manners. For example, while changing the value of the boosting control signal during the wafer test (WT) step in the case where the optimal voltage value is not applied to the boosting control line (FDBL) for each pixel PX. Accordingly, the optimized voltage value of the boosting control signal for each pixel PX can be determined. The average of the optimal voltage values of the pixels PX constituting each pixel row (R1, R2, R3, ∙∙∙, Rn-1, Rn) can be calculated for each pixel row (R1, R2, R3, ∙∙∙, Rn-1, Rn). Accordingly, the optimal voltage value of the boosting control signal for each pixel row (R1, R2, R3, ∙∙∙, Rn-1, Rn) may be stored in the data memory 500. The optimal voltage values of the boosting control signals for each pixel row (R1, R2, R3, ∙∙∙, Rn-1, Rn) may be different from each other. The row drivers 120a, 120b, and 120c of FIG. 13 may provide boosting control signals with different average optimal voltage values to the corresponding pixel rows (R1, R2, R3, ∙∙∙, Rn-1, Rn) based on the optimal voltage values of the boosting control signals for each pixel row (R1, R2, R3, ∙∙∙, Rn-1, Rn) stored in the data memory 500.

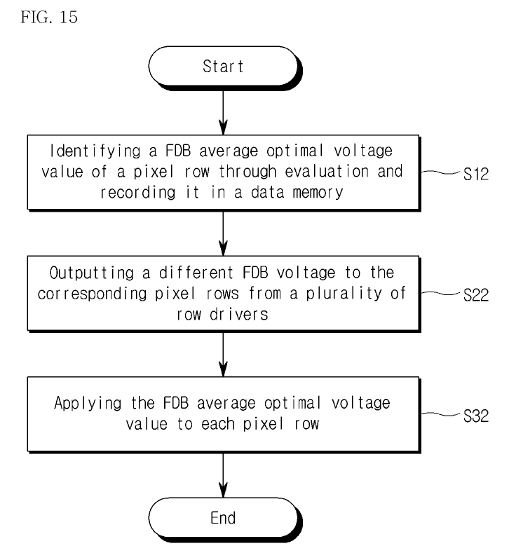

Hereinafter, the method of operating the imaging device described in FIGS. 13 and 14 will be described. While describing the flow chart of FIGS. 15,13 and 14, may be referred to together.

FIG. 15 is a flow chart showing a method of operating an imaging device based on a further embodiment.

Referring to FIGS. 13 and 15 , the method of operating the imaging device based on the present embodiment includes a step (S12) of identifying an average optimal voltage value of a boosting control signal (FDB) of each pixel row through evaluation and then recording it in a data memory 500. In this step, the evaluation may be an evaluation in a black environment or an evaluation in a white environment, and in this embodiment, the evaluation in a white environment will be described as the main focus.

The data memory 500 may store an average optimal voltage value that should be applied to a boosting control line (FDBL) of each pixel row (R1, R2, R3, ∙∙∙, Rn-1, Rn) based on image data (Data_PX) of pixels (PX) constituting each of the pixel rows (see R1, R2, R3, ∙∙∙, Rn-1, Rn in FIG. 13).

For example, the data memory 500 may store a first average optimal voltage value of the boosting control signal of the pixels (PX) of at least one pixel row (e.g., including the first pixel row (R1)), a second average optimal voltage value of the boosting control signal of the pixels (PX) of at least one pixel row (e.g., including the second pixel row (R2)) to which the first average optimal voltage value is not applied, and a third average optimal voltage value of the boosting control signal of the pixels (PX) of at least one pixel row (e.g., including the third pixel row (R3)) to which the first and second average optimal voltage values are not applied.

Next, the method of operating the imaging device based on the present embodiment includes a step (S22) of outputting a different voltage (or average optimal voltage value) of the boosting control signal (FDB) to the corresponding pixel rows from a plurality of row drivers (see 120a, 120b, and 120c of FIG. 13).

Next, the method of operating the imaging device based on the present embodiment includes a step (S32) of applying an average optimal voltage value of the boosting control signal (FDB) to each pixel row.

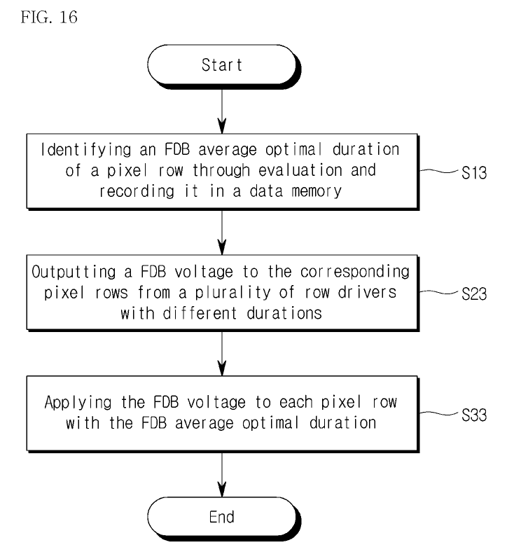

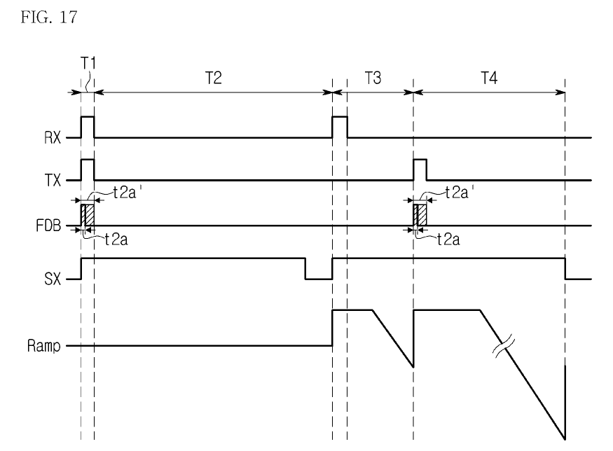

Hereinafter, with reference to FIGS. 16 and 17, a method of compensating for the duration of the boosting control signal (FDB) and an imaging device that compensates will be described.

The method of operating the imaging device based on FIG. 16 and the imaging device are the same as the imaging device described in FIG. 13, but the durations of the control signals (or boosting control signals (FDB)) output from each row driver (see 120a, 120b, and 120c of FIG. 13) may be different from each other. Therefore, the structure of the imaging device based on the present embodiment may be the same as the imaging device described in FIG. 13.

Referring to FIGS. 13 and 16, the method of operating the imaging device based on the present embodiment includes a step (S13) of identifying the average optimal duration of the boosting control signal (FDB) of each pixel row through evaluation and then recording it in the data memory 500. In this step, the evaluation may be an evaluation in a black environment or an evaluation in a white environment, and in one embodiment, the description will be centered on the evaluation in a white environment. In this embodiment, the description will be centered on the evaluation in a white environment. The step (S13) is similar to the step (S12) described in FIG. 15, and thus, a duplicate description will be omitted.

Next, the method of operating the imaging device based on the present embodiment includes a step (S23) of outputting the voltage of the boosting control signal (FDB) to the corresponding pixel rows from a plurality of row drivers (see 120a, 120b, and 120c of FIG. 13) with different durations, respectively.

Next, the method of operating the imaging device based on the present embodiment includes a step (S33) of applying a boosting control signal (FDB) with an average optimal duration to each pixel row.

Based on the present embodiment, the optimal duration of the boosting control signal (FDB) may be different for each pixel, and the duration of the boosting control signal (FDB) applied to each pixel row can be optimized through the boosting control signal (FDB) output from different row drivers 120a, 120b, and 120c.

FIG. 17 is a timing view showing that a booting control ling of one pixel operates at an optimal driving time.

Referring to FIG. 17, a boosting control signal may be applied with a second duration (t2a’) having the same time as the first duration (T1).

Although the present invention has been described with reference to the exemplified drawings, it is to be understood that the present invention is not limited to the embodiments and drawings disclosed in this specification, and those skilled in the art will appreciate that various modifications are possible without departing from the scope and spirit of the present invention. Further, although the operating effects based on the configuration of the present invention are not explicitly described while describing an embodiment of the present invention, it should be appreciated that predictable effects are also to be recognized by the configuration.

1. An imaging device, comprising:
a pixel array comprising first pixels arranged in a first pixel row along a first direction, and second pixels arranged in a second pixel row along the first direction, wherein the second pixel row is spaced apart from the first pixel row along a second direction intersecting the first direction;
a first row driver configured to supply a first control signal to the first pixels of the first pixel row; and
a second row driver configured to supply a second control signal to the second pixels of the second pixel row,
wherein the first control signal and the second control signal are different from each other.

2. The imaging device of claim 1, wherein a voltage value of the first control signal and a voltage value of the second control signal are different from each other.

3. The imaging device of claim 1, further comprising:
a first control line connected to the first row driver and the first pixel row; and
a second control line connected to the second row driver and the second pixel row.

4. The imaging device of claim 3, wherein the first control line and the second control line are different from each other.

5. The imaging device of claim 1, wherein each of the first pixels on the first pixel row and the second pixels on the second pixel row comprise a photodetector, a transfer transistor connected to the photodetector, and a floating diffusion region connected to the transfer transistor.

6. The imaging device of claim 5, wherein the pixel array further comprises a boosting control line forming a capacitance with the floating diffusion region of a first pixel or a second pixel.

7. The imaging device of claim 5, wherein the first control signal and the second control signal are applied to gate electrodes of transfer transistors of the first pixels and the second pixels, respectively.

8. The imaging device of claim 6, wherein the first control signal and the second control signal are applied to the boosting control line forming capacitances with floating diffusion regions of the first pixels and the second pixels, respectively.

9. The imaging device of claim 7, wherein the first control signal has a first average voltage value applied to the gate electrode of the transfer transistor of the pixels included in the first pixel row, the first average voltage value being obtained as an average of voltage values required to turn on each of transfer transistors included in the first pixels, and
the second control signal has a second average voltage value applied to the gate electrode of the transfer transistor of the pixels included in the second pixel row, the second average voltage value being obtained as an average of voltage values required to turn on each of transfer transistors included in the second pixels.

10. The imaging device of claim 5, wherein the first control signal is a first average voltage value applied to a first boosting control line forming capacitances with floating diffusion regions of the first pixels included in the first pixel row, and the second control signal is a second average voltage value applied to a second boosting control line forming capacitances with floating diffusion regions of the second pixels included in the second pixel row.

11. The imaging device of claim 1, wherein the first row driver is disposed on one side of the pixel array in the first direction, and the second row driver is disposed on the other side of the pixel array in the first direction.

12. The imaging device of claim 11, wherein the pixel array further comprises switches respectively arranged between adjacent ones of the first pixels of the first pixel row and between adjacent ones of the second pixels of the second pixel row.

13. The imaging device of claim 12, further comprising:
a switch controller connected to each of the switches.

14. An imaging device, comprising:
a pixel array comprising a first pixel row of first pixels arranged along a first direction, and a second pixel row of second pixels arranged along the first direction, wherein the second pixel row is spaced apart from the first pixel row along a second direction intersecting the first direction;
a first row driver configured to supply a first control signal of a first duration to the first pixels of the first pixel row; and
a second row driver configured to supply a second control signal of a second duration to the second pixels of the second pixel row,
wherein the first duration and the second duration are different from each other.

15. The imaging device of claim 14, further comprising:
a first control line connected to the first row driver and the first pixel row; and
a second control line connected to the second row driver and the second pixel row.

16. The imaging device of claim 15, wherein the first control line and the second control line are different from each other.

17. A method of operating an imaging device, comprising:
determining an average voltage value of a control signal of pixels of a pixel row among a plurality of pixel rows included in the imaging device;
storing the average voltage value of the control signal in a data memory;
outputting a control signal based on the average voltage value to the pixel row from a row driver among a plurality of row drivers included in the imaging device; and
applying the average voltage value to the pixel row.

18. The method of operating the imaging device of claim 17, wherein at least one of the pixels comprises a photodetector, a transfer transistor connected to the photodetector, and a floating diffusion region connected to the transfer transistor.

19. A method of operating an imaging device, comprising:
determining an average duration of a control signal of pixels of a pixel row among a plurality of pixel rows included in the imaging device;
storing the average duration of the control signal in a data memory;
outputting the control signal with the average duration to the pixel row from a row driver among a plurality of row drivers included in the imaging device; and
applying the control signal with the average duration to the pixel row.

20. The method of operating the imaging device of claim 19, wherein at least one of the pixels comprises a photodetector, a transfer transistor connected to the photodetector, and a floating diffusion region connected to the transfer transistor.
